(19) United States
(12) Patent Application Publication
(10) Pub. No.: US 2009/0206859 A1
(43) Pub. Date: Aug. 20, 2009

(54) PROBE DEVICE HAVING A LIGHT SOURCE THEREON

(75) Inventors: Jason A. Swaim, Castle Rock, CO (US); James E. Cannon, Colorado Springs, CO (US); Kenny Johnson, Colorado Springs, CO (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(73) Assignee: Agilent Technologies, Inc., Palo Alto, CA (US)

(21) Appl. No.: 12/034,637

(22) Filed: Feb. 20, 2008

(51) Int. Cl. G01R 1/067

(52) U.S. Cl. 324/756

(57) ABSTRACT

A probe device is provided that has light source thereon that can be activated and deactivated. In accordance with an embodiment, the light source operates as a visual indicator to provide a visual indication of whether a good connection exists between the tips of the probe device and the intended contact points on the DUT. In accordance with another embodiment, the light source operates as a source of illumination to illuminate the probe tips and the contact pads on the DUT as the user is attempting to place the probe tips in contact with the contact pads on the DUT. In accordance with yet another embodiment, the light source performs the dual functions of providing a visual indication of connection status and of illuminating the probe device tips and the intended contact points on the DUT.

### TECHNICAL FIELD OF THE INVENTION

The invention relates to electrical probe devices used to measure electrical signals on conductors of a device under test (DUT). More particularly, the invention relates to a probe device having a light source located thereon.

### BACKGROUND OF THE INVENTION

A probe device is a device having two arms, sometimes referred to as “substrates” or “blades”, which are mechanically coupled to each other at distal ends of the arms, and having electrically conductive tips secured to the proximal ends of the arms. During testing of a DUT, the tips are placed in contact with respective conductors of the DUT for sensing electrical signals propagating though the conductors of the DUT. The probe device is typically adjustable to allow the probe tips to be moved closer to and farther away from each other such that a span width between the tips is adjustable to accommodate varying DUT physical layouts. The electrical signals sensed by the tips are passed from the tips to other electrical circuits disposed on the arms that prepare the signals for input to a differential amplifier circuit. The arms are each electrically coupled at their distal ends to respective electrical wires, such as coaxial cables, which receive the amplified differential signals output from the amplifier circuit and pass the amplified signals to test and measurement equipment, such as an oscilloscope.

In order for the user to make physical contact between the tips of the probe device and the conductors of the DUT, the user visually observes the positions of the tips relative to the conductors and moves the tips until they are in physical contact with desired locations on the conductors of the DUT. This is becoming increasingly difficult due to the physical dimensions on the DUT components becoming increasingly smaller. In addition, modem high-speed probing is typically performed differentially, which requires that the tips be placed in contact with separate points on the DUT simultaneously. With pads on the DUT now being on the order of 1/4 millimeter (mm) in diameter, it is becoming almost impossible for the user to see well enough to make good contact between the probe tips and the pads.

Solutions to this problem have been proposed or implemented. For example, Agilent Technologies, Inc., the assignee of the present application, offers a 19600 series Logic Analyzer that uses a software indicator that detects when good contact is made between the probe tips and the pads of the DUT and triggers an on-screen indication that is displayed on the scope display screen of the Logic Analyzer to inform the user that good contact has been made. This system employs a user-adjustable threshold voltage and circuitry that detects when the voltage measured by the tips exceeds the threshold voltage level. When the measured signal exceeds the threshold level, the on-screen indication is triggered.

While this solution is satisfactory in many cases, one problem with this solution is that the user is required to look at the scope display screen to determine when good contact has been made between the probe tips and the DUT contact pads. Because of the dexterity required by the user when performing this task, it can be difficult for the user to watch the screen while trying to place the probe tips in contact with the DUT contact pads. In addition, once contact has been made, it can be difficult for the user to maintain contact while viewing the scope screen.

Accordingly, a need exists for a probe device having a visual indicator of connection status that is easily viewable by the user as the user is attempting to place the tips in contact with the contact areas on the DUT and as the user is attempting to maintain contact between the tips and the contacts on the DUT.

Yet another difficulty associated with current probe devices is that they provide no source of illumination for illuminating the probe tips or the contact points on the DUT. Currently, the only way to illuminate the tips and the contact points on the DUT is to have a person hold a flashlight or lamp over the area in question as the user attempts to navigate the probe device to bring the tips into contact with the contacts on the DUT. Often times, the hand holding the probe device, or large components on the circuit board, cast shadows over the area in question. Consequently, this solution is inadequate for its intended purpose. Accordingly, a need also exists for a way to satisfactorily illuminate the probe device tips and the areas on the DUT in question as the user attempts to place the tips in contact with the contact points on the DUT.

### SUMMARY OF THE INVENTION

The invention provides a probe device having a light source, a system that incorporates the probe device, and a method for placing a light source in at least a first mode if a first control signal is sent to the probe device. The probe device comprises a probe device housing having a distal end connected to first and second conductive wires, first and second arms each having a proximal end and a distal end, first and second electrically conductive tips secured to the first and second arms, respectively, a light source secured to the probe device housing, and light source indicator driver circuitry in the housing. The driver circuitry is configured to cause the light source to be placed in a first mode if a first control signal is received in the driver circuitry.

The system comprises a probe device having a housing to which a light source is secured and a scope apparatus. The scope apparatus comprises processing circuitry configured to receive electrical signals sensed by first and second tips of the probe device and sent over the first and second conductive wires, respectively, to the scope apparatus. The scope apparatus determines whether or not the electrical signals sensed by the first and second tips indicate that the first and second tips are in good electrical contact with first and second contact areas, respectively, on the DUT. If the scope apparatus determines that the electrical signals sensed by the first and second tips indicate that the first and second tips are in good electrical contact with the first and second contact areas, respectively, on the DUT, the scope apparatus causes a first control signal to be sent over a communication link to light source indicator driver circuitry of the probe device. The driver circuitry of the probe device causes the light source to be placed in a first mode if the first control signal is sent by the scope apparatus to the probe device.

The method comprises receiving an indication of a difference between electrical voltage signals sensed by first and second probe tips of a probe device, determining whether or not the received indication indicates that the first and second tips are in good electrical contact with first and second contact areas, respectively, on the DUT, if a determination is made that the received indication indicates that the first and second tips are in good electrical contact with first and second contact areas, respectively, on the DUT, causing a light source on the probe device to be placed in a first mode and if a determination is made that the received indication indicates that the first and second tips are not in good electrical contact with first and second contact areas, respectively, on the DUT, causing a light source on the probe device to be placed in a second mode.

These and other features and advantages of the invention will become apparent from the following description, drawings and claims.

### BRIEF DESCRIPTION OF THE DRAWINGS

FIG. 1 illustrates a top perspective view of the probe device of the invention in accordance with an illustrative embodiment, wherein the probe device includes a connection status indication light source positioned near the tips of the probe device.

FIG. 2 illustrates a block diagram of the system of the invention in accordance with an embodiment comprising the probe device such as that shown in FIG. 1 and a scope apparatus that communicates with the probe device via a wired link.

FIG. 3 illustrates a block diagram of the indicator circuitry of the probe device shown in FIG. 2 in accordance with an embodiment.

FIG. 4 illustrates a block diagram of the system of the invention in accordance with another illustrative embodiment comprising a probe device such as that shown in FIG. 1 and a scope apparatus that communicates with the probe device via a wireless link.

FIG. 5 illustrates a block diagram of the indicator circuitry of the probe device shown in FIG. 4 in accordance with another illustrative embodiment.

FIG. 6 illustrates a flowchart that represents the method in accordance with an illustrative embodiment of the invention for providing a visual indication of connection status for a probe device.

FIG. 7 illustrates a front plan view of a front faceplate of the probe device shown in FIG. 2 having a light source located thereon for illuminating the probe tips of the probe device and areas on the DUT in close proximity to the tips.

### DETAILED DESCRIPTION OF ILLUSTRATIVE EMBODIMENTS

In accordance with the invention, a probe device is provided that has a light source thereon. In accordance with an embodiment, the light source operates as a visual indicator to provide a visual indication of whether a good connection exists between the tips of the probe device and the intended contact points on the DUT. In accordance with another embodiment, the light source operates as a source of illumination to illuminate the probe tips and the contact pads on the DUT as the user is attempting to place the probe tips in contact with the contact pads on the DUT. In accordance with another embodiment, the light source performs the dual functions of providing a visual indication of connection status and of illuminating the probe device tips and the intended contact points on the DUT.

A variety of probe device configurations are possible that will enable the goals of the invention to be achieved. A few examples of possible configurations will now be described with reference to the figures. It should be noted, however, that the invention is not limited to the probe device configurations described herein, as will be understood by persons of ordinary skill in the art in view of the following description and claims. For example, although the invention is being described herein with reference to a differential probe device for illustrative purposes, the invention is suitable for use with probe devices that are not differential probe devices. It should also be noted that the figures are not necessarily drawn to scale. The figures are intended to demonstrate the principles and concepts of the invention without being limited in terms of dimensions or shape.

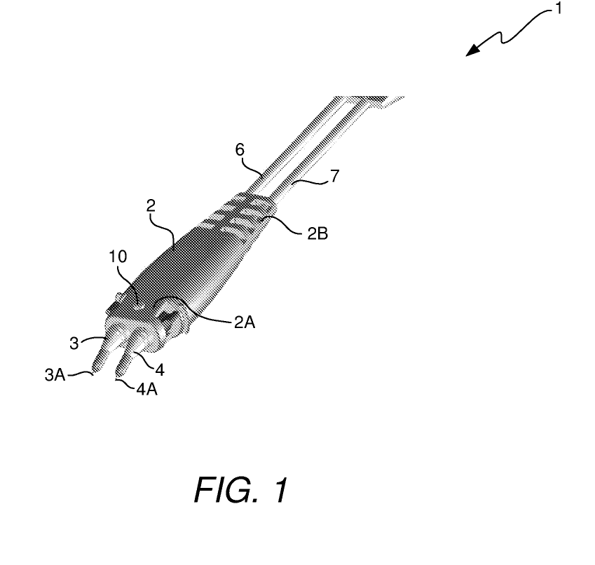

FIG. 1 illustrates a top perspective view of an electrical probe device 1 of the invention in accordance with an illustrative embodiment, wherein the probe device includes a light source for providing a visual indication of connection status. The probe device 1 has a housing 2 that houses electrical circuitry of the probe device 1. The probe device 1 has two arms 3 and 4, each of which has a conductive tip 3A and 4A, respectively, disposed on the distal ends thereof. The proximal ends of the arms 3 and 4 are mechanically coupled to the distal end 2A of the housing 2. The proximal end 2B of the housing 2 includes electrical connectors (not shown) for connecting the probe device 1 to respective electrical cables 6 and 7, such as coaxial cables, for example. The electrical signals measured by the probe tips 3A and 4A are conditioned by electrical circuitry (not shown) contained within the housing 2 and then transmitted along cables 6 and 7 to the equipment (not shown) with which the probe device 1 is used, such as, for example, a logic analyzer system. Because the probe device 1 may be used with various types of measurement and testing equipment, the equipment with which the probe device 1 is used will be referred to hereinafter as simply “the scope apparatus”.

The probe device 1 includes a light source 10 that provides an indication of the electrical connection status of the probe device 1. Preferably, the light source 10 is located on the upper surface of the probe device 1 as shown on the distal end 2A of the housing 2. Thus, the light source 10 is clearly visible to a person who is using the probe device 1 as that person is attempting to place the probe tips 3A and 4A in physical contact with the contact pads (not shown) of the DUT (not shown). This makes it unnecessary for the person using the probe device 1 to turn away from the probe tips 3A and 4A to look at the scope screen of the logic analyzer to ascertain whether an electrical connection has been made or is being maintained. This feature of the invention also allows persons with poor eyesight to know when the probe tips 3A and 4A have been correctly placed on contact areas of the DUT. This feature of the invention ensures that even as the physical dimensions of components on the DUT continue to decrease in size, and therefore become more difficult to accurately probe, the user will know when the tips 3A and 4A are in contact with the intended contact areas on the DUT.

The light source 10 is typically a light emitting diode (LED), but may be any type of suitable illumination device. LEDs are available that are very small in size, remain at relatively low temperatures during operation, and have relatively long life spans. These characteristics of LEDs make them highly suitable for placement on the probe device 1. In the case where an LED is used for this purpose, the LED 10 illuminates when an appropriate electrical connection has been made between the probe tips 3A and 4A and the contact points on the DUT. What constitutes an “appropriate” electrical connection preferably is user definable through the scope user interface. An “appropriate” electrical connection may be defined in several ways. For example, one technique is to simply cause the LED 10 to be illuminated when there is a non-zero voltage level between the probe tips 3A and 4A. Thus, in this case, an “appropriate” electrical connection is one that results in a non-zero voltage level between the probe tips 3A and 4A. A threshold voltage level may be defined through the user making an appropriate selection via the scope user interface. If the voltage measured between the tips 3A and 4A is equal to or exceeds this user-selected threshold voltage, the LED 10 may be activated (i.e., turned on). If the voltage measured between the tips 3A and 4A falls below the user-selected threshold voltage, the LED 10 may be deactivated (i.e., turned off).

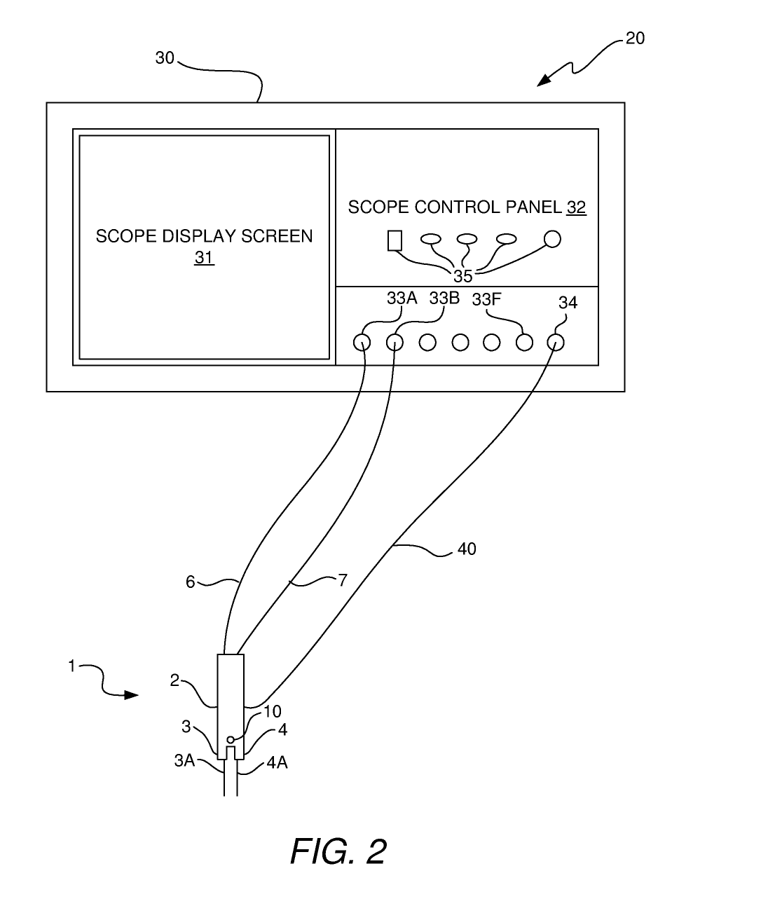

In order to activate and deactivate the LED 10, a source of power is typically needed in the probe device 1. A suitable power source for this purpose is a small dc battery, which may be located in the housing 2 near its distal end 2A. Also, in order to provide user-customization to enable user-defined settings (e.g., the threshold voltage level) to be applied by the user, communication between the scope apparatus and the circuitry in the probe device 1 that controls the LED 10 is needed. The cables 6 and 7 that communicate signals from the probe device 1 to the scope apparatus generally are not suitable for sending control signals from the scope apparatus to the probe device 1. In order to allow the scope apparatus to control the Led 10 based on the voltage sensed by the tips 3A and 4A, the scope apparatus needs to have some way of communicating control signals to the circuitry in the probe device 1 that controls the LED 10. The manner in which this can be accomplished will now be described with reference to a few illustrative embodiments depicted in FIGS. 2-5.

FIG. 2 illustrates a block diagram of the system 20 of the invention in accordance with an embodiment comprising the probe device 1 shown in FIG. 1 and a scope apparatus 30. The scope apparatus 30 may be, for example, a known logic analyzer apparatus or oscilloscope. The scope apparatus 30 includes a display screen 31, a control panel 32, input ports 33A-33F, and at least one output port 34. The input ports 33A and 33B are connected to ends of radio frequency (RF) wires 6 and 7, which may be, for example, coaxial cables. The opposite ends of the RF wires 6 and 7 are connected to the proximal end 2B (FIG. 1) of the housing 2 of the probe device 1, as described above with reference to FIG. 1. Signals sensed by the tips 3A and 4A of the probe device 1 are conditioned by circuitry (not shown) within the probe device 1. The conditioned signals are transmitted over RF wires 6 and 7, respectively, to the scope apparatus 30.

In the scope apparatus 30, the sensed signals are received and processed in a known manner in accordance with the test or tests being performed by the scope apparatus 30. The scope apparatus 30 then causes signal traces corresponding to the sensed signals to be displayed on the display screen 31. Various selector switches 35 are provided on the control panel 32 to enable the user to select the manner in which the signals measured by the probe device 1 are to be processed and displayed on the display screen 31. Alternatively, the scope apparatus 30 may have a control panel that is part of a graphical user interface (GUI), in which case menus and buttons displayed on a display device (e.g., display screen 31) are provided to allow the user to make appropriate selections.

In accordance with this embodiment, the scope apparatus 30 includes a processor or controller (not shown) that performs an algorithm that determines whether the difference between the voltage levels sensed by the tips 3A and 4A (i.e., the differential voltage level) is equal to or greater than a particular threshold level, TH_{DIFF}. If so, then the algorithm performed by the scope apparatus 30 causes a first indicator control signal, S_{IN1}, to be sent via a conductive wire 40 to the probe device 1. The conductive wire 40 may be, for example, an RF wire such as a coaxial cable. The coaxial cables 6 and 7 that are typically used to send the differential signals from the probe device 1 to the scope apparatus 30 sometimes include extra wires, one of which could be used as wire 40 to communicate the control signal S_{IN1} from the scope apparatus 30 to the probe device 1.

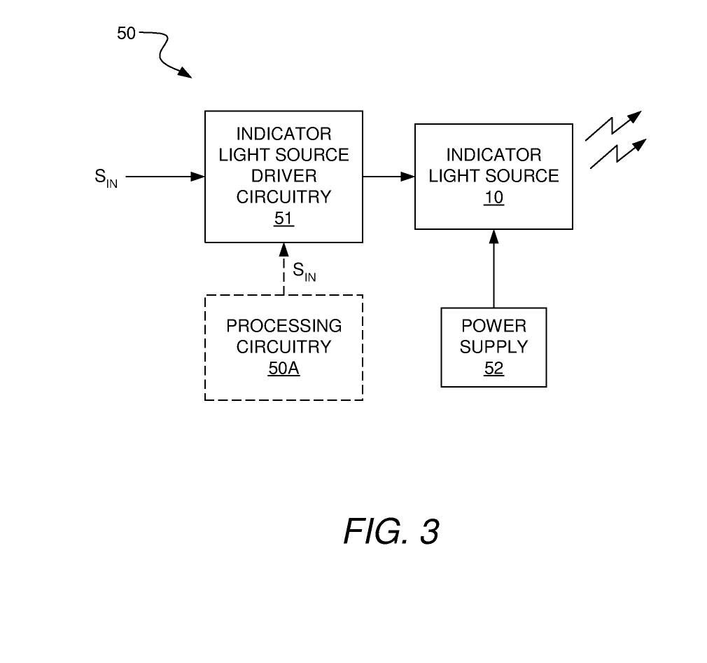

In the probe device 1, indicator circuitry, which is described below with reference to FIG. 3, receives the control signal S_{IN1} and causes the indicator light source 10 to be placed in a first mode. The first mode is typically activation of the light source 10, i.e., the light source is illuminated. If the scope apparatus 30 determines that the sensed differential voltage level is less than TH_{DIFF}, then the scope apparatus 30 causes a second indicator control signal, S_{IN2}, to be sent via the conductive wire 40 to the probe device 1. In the probe device 1, the indicator circuitry (FIG. 3) receives the control signal SIN₂ and causes the indicator light source 10 to be placed in a second mode. The second mode is typically deactivation of the light source 10, i.e., the light source 10 is darkened.

Other characteristics associated with the signals measured by the probe device tips 3A and 4A could be used instead of, or in combination with, the voltage level to determine whether an appropriate electrical connection has been made between the tips 3A and 4A and the contact pads on the DUT. For example, the frequency of the measured signal could be used to determine whether an appropriate electrical connection has been made. The invention is not limited with respect to which characteristics of the measured signal are used to make this determination.

Also, although the algorithm that processes the signals sensed by the probe tips 3A and 4A to determine whether the light source 10 is to be illuminated or darkened is typically performed by the scope apparatus 30, this algorithm could instead be performed by processing circuitry contained within the probe device 1 itself. For example, probe devices sometimes include integrated circuits (ICs), such as application specific integrated circuits (ASICs), for example. In such cases, the algorithm described above could be performed within the ASIC of the probe device, in which case the wired communication link 40 would not be needed because the signals S_{IN1} and S_{IN2} would be produced by and used by circuitry within the probe device 1.

FIG. 3 illustrates a block diagram of the indicator circuitry 50 of the probe device 1 shown in FIG. 2 in accordance with an embodiment. In accordance with this embodiment, the indicator circuitry 50 includes indicator light source driver circuitry 51 that receives the signal S_{IN1} or S_{IN2} propagating on wire 40 (or produced by circuitry within the probe device) and processes the received signal to produce an output signal that is delivered to the indicator light source 10. The indicator circuitry 50 also includes the indicator light source 10 (FIGS. 1 and 2), which receives the output signal from the indicator light source driver circuitry 51. The output signal received by the indicator light source 10 from the indicator light source driver circuitry 51 causes the indicator light source 10 to either be activated or deactivated depending on whether the input signal received by the indicator light source driver circuitry 51 is S_{IN1} or S_{IN2} The indicator circuitry 50 includes a power supply 52, which is typically a small dc battery, for supplying power to the indicator light source 10. Alternatively, power could be supplied to the probe device 1 by the scope apparatus 30, in which case the power supply 52 is not needed.

If the algorithm that processes the signals sensed by the probe device tips 3A and 4A and produces the indicator control signals S_{IN1} and S_{IN2} is to be performed within the probe device 1 instead of in the scope apparatus 30, the circuitry 50 shown in FIG. 3 will include processing circuitry 50A (e.g., an ASIC) for performing these tasks. In this case, the processing circuitry 50A will process the signals sensed by the probe tips 3A and 4A and produce the indicator control signals S_{IN1} and S_{IN2}, which are then provided to the indicator light source driver circuitry 51.

The indicator control signals S_{IN1} and S_{IN2} may be signals that have different voltage levels. For example, control signal S_{IN1} may be a voltage signal having a high voltage level (e.g., 5 volts) and control signal S_{IN2} may be a voltage signal having a low voltage level (e.g., 0 volts). In this case, the indicator light source driver circuitry 51 will receive the signals S_{IN1} and S_{IN2} and produce corresponding high and low output signals, respectively, which, in turn, cause the indicator light source 10 to be activated and deactivated, respectively. Of course, the indicator light source driver circuitry 51 may be configured with inverter circuitry (not shown) such that a high-level input signal is converted into a low-level output signal, and vice versa. In the latter case, a low-level S_{IN1} signal received by the indicator light source driver circuitry 51 will result in a high-level driver signal being output from the indicator light source driver circuitry 51, whereas a high-level S_{IN2} signal received by the indicator light source driver circuitry 51 will result in a low-level driver signal being output from the indicator light source driver circuitry 51.

Alternatively, the indicator control signals S_{IN1} and S_{IN2} may be signals that have the same voltage level, in which case the indicator light source driver circuitry 51 contains toggle circuitry (e.g., flip-flop circuitry). In this case, if S_{IN1} is a signal having a high voltage level, the output signal produced by the indicator light source driver circuitry 51 is a signal having a high voltage level. If the next signal received by the indicator light source driver circuitry 51 is S_{IN2} having the same high level as the immediately preceding signal S_{IN1}, the toggle circuitry contained in the indicator light source driver circuitry 51 will toggle its output, causing the output signal produced by the indicator light source driver circuitry 51 to have a low level. The indicator light source driver circuitry 51 may be configured in virtually an infinite number of ways to achieve the functions necessary for driving the indicator light source 10.

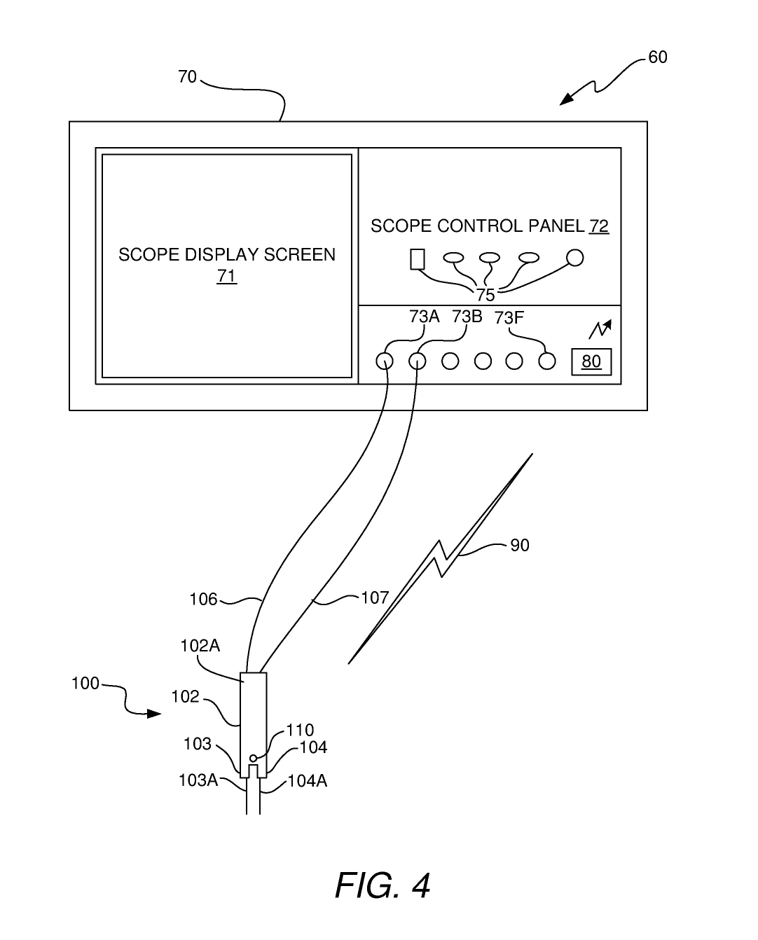

FIG. 4 illustrates a block diagram of the system 60 of the invention in accordance with another illustrative embodiment. As with the embodiment represented by FIG. 2, the system 60 in accordance with this embodiment comprises a scope apparatus 70 and a probe device 100, which is similar or identical to the probe device 1 shown in FIG. 1. The scope apparatus 70 may be, for example, a known logic analyzer apparatus. The scope apparatus 70 includes a display screen 71, a control panel 72, input ports 73A-73F, and a wireless transmitter 80. The input ports 73A and 73B are connected to ends of RF wires 106 and 107, which may be, for example, coaxial cables. The opposite ends of the RF wires 106 and 107 are connected to the proximal end 102A of the housing 102 of the probe device 100. Signals sensed by the tips 103A and 104A of the probe device 100 are conditioned by circuitry (not shown) within the probe device 100. The conditioned signals are transmitted over RF wires 106 and 107, respectively, to the scope apparatus 70.

In the scope apparatus 70, the sensed signals are received and processed in a known manner in accordance with the test or tests being performed by the scope apparatus 70. The scope apparatus 70 then causes signal traces corresponding to the sensed signals to be displayed on the display screen 71. Various selector switches 75 provided on the control panel 72 are used by the user to select the manner in which the signals measured by the probe device 100 are processed and displayed on the display screen 71. Alternatively, the scope apparatus 70 may have a control panel that is part of a GUI, in which case menus and buttons displayed on a display device (e.g., display screen 71) are provided to allow the user to make appropriate selections.

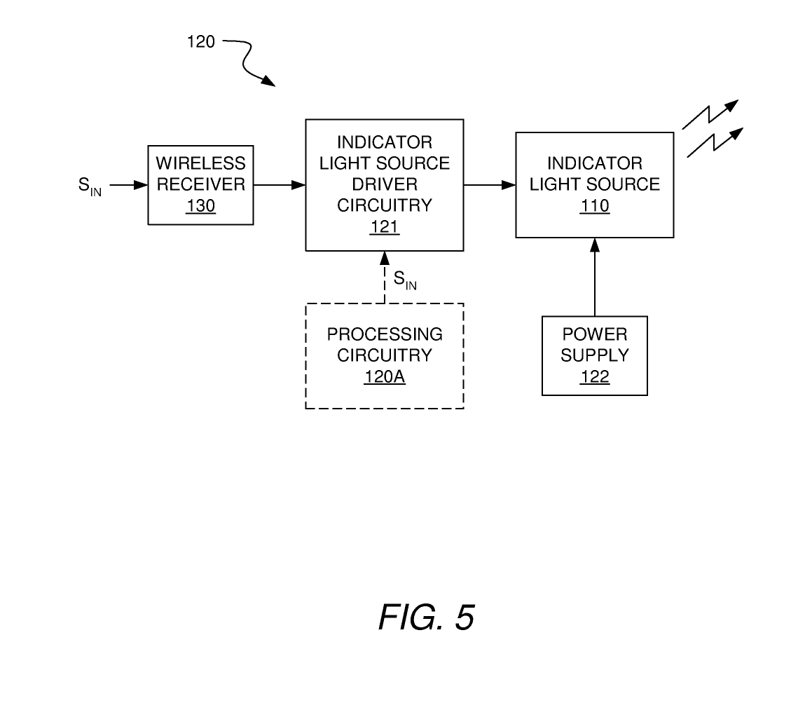

The scope apparatus 70 performs an algorithm in accordance with the invention that determines whether the difference between the voltage levels sensed by the tips 103A and 104A (i.e., the differential voltage level) is equal to or greater than TH_{DIFF}. If so, then the algorithm performed by the scope apparatus 70 causes a first wireless indicator control signal, S_{IN1}, to be generated by wireless transmitter 80 and sent over wireless link 90 to the probe device 100. In the probe device 100, indicator circuitry (described below with reference to FIG. 5) receives the control signal S_{IN1} and causes the indicator light source 110 to be placed in the first mode, e.g., the light source 110 is illuminated.

If the scope apparatus 70 determines that the sensed differential voltage level is less than TH_{DIFF}, then the scope apparatus 70 causes a second indicator control signal, S_{IN2}, to be generated by the wireless transmitter 80 and sent via the wireless link 90 to the probe device 100. In the probe device 100, indicator circuitry (FIG. 5) receives the control signal S_{IN2} and causes the indicator light source 110 to be placed in a second mode, e.g., the light source 110 is deactivated to cause it to darken.

As indicated above with reference to FIG. 2, other characteristics associated with the signals measured by the probe device tips 103A and 104A may be used instead of, or in combination with, the sensed voltage level to determine whether an appropriate electrical connection has been made between the tips 103A and 104A and the contact pads on the DUT. For example, the frequency of the measured signal could be used to determine whether an appropriate electrical connection has been made. The invention is not limited with respect to which characteristics of the measured signal are used to make this determination.

Also, although the algorithm that processes the signals sensed by the probe tips 103A and 104A to determine whether the light source 110 is to be illuminated or darkened is typically performed by the scope apparatus 70, this algorithm could instead be performed by processing circuitry contained within the probe device 100. For example, the algorithm described above could be performed within an ASIC of the probe device 100, in which case the wireless communication link 90 would not be needed because the signals S_{IN1} and S_{IN2} would be produced by and used by circuitry within the probe device 100.

FIG. 5 illustrates a block diagram of the indicator circuitry 120 of the probe device 100 shown in FIG. 4 in accordance with another illustrative embodiment. In accordance with this embodiment, the indicator circuitry 120 includes a wireless receiver 130, indicator light source driver circuitry 121, indicator light source 110, and a power supply 122, which is typically a small dc battery. Alternatively, power could be supplied to the probe device 100 by the scope apparatus 70, in which case the power supply 122 is not needed. The wireless receiver 130 receives the signal S_{IN1} or S_{IN2} produced by the wireless transmitter 80 and decodes the received wireless signals, which are then provided to the indicator light source driver circuitry 121. The indicator light source driver circuitry 121 receives the decoded signals and converts them into indicator light source driver signals, which are then output to the indicator light source 110. If the control signal S_{IN} received by the wireless receiver 130 is signal S_{IN1}, the indicator light source signal output to the indicator light source 110 causes the indicator light source 110 to be activated, e.g., illuminated. If the control signal S_{IN} received by the wireless receiver 130 is signal S_{IN2}, the indicator light source driver signal output to the indicator light source 110 causes the indicator light source 110 to be deactivated, e,g., darkened.

If the algorithm that processes the signals sensed by the probe device tips 103A and 104A and produces the indicator control signals S_{IN1} and S_{IN2} is to be performed within the probe device 100 instead of in the scope apparatus 70, the circuitry 120 shown in FIG. 5 will include processing circuitry 120A (e.g., an ASIC) for performing these tasks. In this case, the processing circuitry 120A will process the signals sensed by the probe tips 103A and 104A and produce the indicator control signals S_{IN1} and S_{IN2}, which are then provided to the indicator light source driver circuitry 121.

The indicator light source driver circuitry 121 may have various configurations similar to those described above with reference to the indicator light source driver circuitry 51 shown in FIG. 3. Therefore, the signals S_{IN1} and S_{IN2} may have high and low levels, respectively, low and high levels, respectively, or the same level. Regardless of the configuration selected for the indicator light source driver circuitry 121, preferably the S_{IN1} signal causes the indicator light source 110 to be illuminated and the S_{IN2} signal causes the indicator light source 110 to be darkened.

It should be noted that the threshold voltage level, TH_{DIFF}, may be set by the user. For example, with reference to FIG. 4, TH_{DIFF} may be set by the user through one of the controls 75 of the control panel 72. The level that is selected for TH_{DIFF} depends on the circumstances, but generally may be any non-zero voltage level. Also, although the indicator light sources 10 and 110 have been described above with respect to FIGS. 1-5 as being either illuminated or darkened to indicate whether a good connection exists between the tips of the probe device, other indications of connection status may be used. For example, the indicator light source may change color to indicate connection status. In this case, the indicator light source may provide red color illumination when the connection status is not satisfactory and may provide green color illumination when the connection status is satisfactory, or vice versa. As another alternative, the indicator light source may provide continuous white light illumination when the connection status is satisfactory and provide flashing white light illumination when the connection status is not satisfactory. An example of another alternative would be to provide multiple indicator light sources on the probe device. In this case, one of the light sources might be illuminated and the other darkened when the connection status is satisfactory, and vice versa. Those of ordinary skill in the art will understand, in view of the description provided herein, that other modifications to the embodiments described herein are also possible.

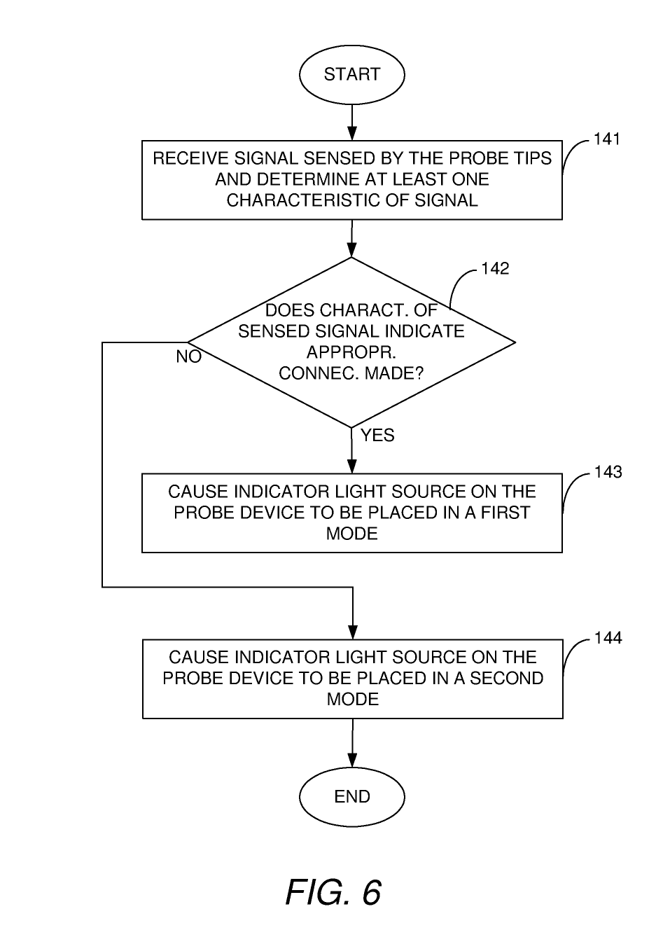

FIG. 6 illustrates a flowchart that represents the method in accordance with an illustrative embodiment for providing a visual indication of connection status for a probe device. An electrical signal sensed by the probe device is received in a processor and evaluated to determine at least one characteristic (e.g., voltage level) of the signal, as indicated by block 141. A determination is then made as to whether this characteristic indicates that an appropriate connection has been made between the probe device and the DUT (e.g., does sensed voltage level exceed TH_{DIFF}), as indicated by block 142. As described above with reference to FIGS. 2 and 4, the processor or controller of the scope apparatus typically performs this algorithm, although this algorithm could instead be performed by some other device, e.g., by processing circuitry within the probe device itself. This algorithm is typically performed in software in a processor, but may be performed in software, hardware, or in a combination of software and hardware and/or firmware.

If a determination is made at block 142 that an appropriate connection has been made, then the indicator light source on the probe device is caused to be placed in a first mode, as indicated by block 143. This first mode typically corresponds to the indicator light source being illuminated. If a determination is made at block 142 that an appropriate connection has not been made, then the indicator light source on the probe device is caused to be placed in a second mode, as indicated by block 144. This second mode typically corresponds to the indicator light source being darkened.

If the algorithm represented by the flowchart shown in FIG. 6 is performed in software or firmware executed by some type of processor, the corresponding computer code is typically stored in some type of computer-readable medium (not shown). The computer-readable medium is typically a solid state memory device such as, for example, a random access memory (RAM) device, a read-only memory (ROM) device, a programmable ROM (PROM) device, an erasable PROM (EPROM) device, a flash memory device, etc. However, other non-solid state memory devices, such as magnetic tape, magnetic disks, optical disks, etc., may also be used for this purpose.

The processor that performs the algorithm represented by the flowchart shown in FIG. 6 may be any type of suitable computational device, including, for example, a microprocessor, a microcontroller, a programmable logic array (PLA), a field programmable gate array (FPGA), an application specific integrated circuit (ASIC), etc. Also, these processing tasks may be performed by a single processor or they may be distributed over multiple processors, as will be understood by persons of ordinary skill in the art in view of the description provided herein.

In accordance with another illustrative embodiment of the invention, the light source 10 (FIG. 1) or 110 (FIG. 4) may be used to illuminate the probe tips 3A and 4A (FIG. 1) and 103A and 104A (FIG. 4). As stated above, due to the components of the DUTs becoming increasingly smaller in size, it is becoming increasingly difficult to see the points on the DUT with which the tips are to be placed in contact. Having a source of illumination on the probe device near the tips allows the points of contacts on the DUT and the tips of the probe device to be easily viewed without shadows as the user attempts to place the tips in contact with the contact points on the DUT. The location of the light source on the probe device is not limited to any particular location. Preferably, the light source is no more than about 10 millimeters (mm) away from the DUT when the tips are in contact with the contact points on the DUT.

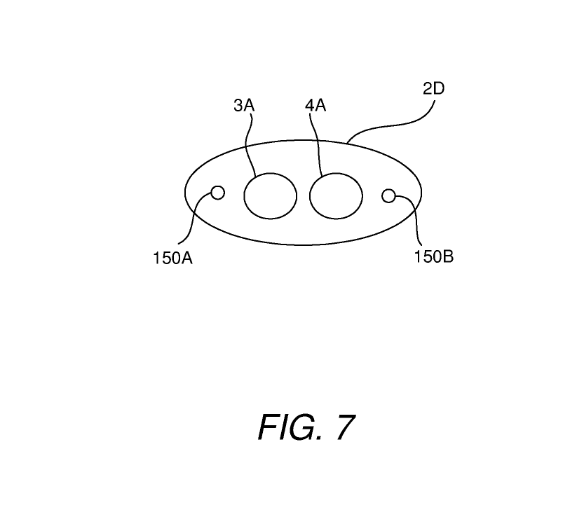

FIG. 7 illustrates a front plan view of a front faceplate 2D of the probe device 1 shown in FIG. 2 having a light source located thereon for illuminating the probe tips 3A and 4A. In accordance with this illustrative embodiment, the light source comprises headlights 150A and 150B, which illuminate the tips 3A and 4A of the probe device as well as locations on the DUT in close proximity to the tips 3A and 4A. A variety of light sources are available that are suitable for this purpose. For example, LEDs are available in several colors and in white that produce high optical output intensity levels, which are suitable for this purpose. Preferably, the light source that is used for this purpose is a diffuse light source, or is used in conjunction with a diffuser element that causes the light emitted by the light source to be diffuse. One or more focusing elements, or optically directive elements, may be included on the probe device for focusing or directing the light emitted by the light source toward the probe tips and the DUT. The light source 150A, 150B may be, for example, a ring of LEDs. Using a ring of LEDs as the light source helps eliminate shadows. The light source may be adjustable so that the level of illumination intensity provided by the light source is variable. Being able to vary the illumination intensity of the light source allows a desired depth of focus to be achieved.

In accordance with yet another embodiment of the invention, the light source on the probe device performs the dual functions of providing a visual indication of connection status and of illuminating the DUT to enable the user to easily see the contact points on the DUT as the user attempts to place the probe tips in contact with the contact points on the DUT. For example, the light source 150A, 150B shown in FIG. 7 may be illuminated continuously while the probe device is in use. Thus, the light source 150A, 150B is illuminated as the user is attempting to place the probe tips 3A and 4A in contact with the contact points on the DUT (not shown). Once the user has placed the probe tips 3A and 4A with the respective contact points on the DUT, the light source 150A, 150B is darkened.

To provide an example of the manner in which this embodiment may be carried out, it will be assumed that a white light LED is used as the light source 150A, 150B. With reference to FIGS. 2 and 7, one of the controls 35 of the control panel 32 may be used to illuminate the white-light LEDs 150A, 150B when the user begins using the system 20. The LEDs 150A, 150B remain illuminated until the user has placed the probe tips 3A and 4A in contact with the respective contact points on the DUT. During use, the algorithm described above with reference to FIG. 6 determines whether the sensed differential voltage is equal to or greater than TH_{DIFF}, and if so, causes the LEDs 150A, 150B to be darkened by sending a corresponding control signal S_{IN1} over the wired link 40 (or over the wireless link 90 in FIG. 4) to the probe device 1. If the algorithm determines that the sensed differential voltage is less than TH_{DIFF}, the algorithm causes the LEDs 150A, 150B to be illuminated by sending a corresponding control signal S_{IN2} over the wired link 40 (or over the wireless link 90) to the probe device 1.

It should be noted that the invention has been described with reference to illustrative embodiments for the purpose of describing the principles and concepts of the invention. Those skilled in the art will understand, in view of the description provided herein, that many modifications may be made to the embodiments described herein without deviating from the scope apparatus of the invention.

What is claimed is:

1. A probe device for use in measuring electrical signals on a device under test (DUT), the probe device comprising:
a probe device housing having a proximal end and a distal end, the distal end of the housing being connected to first and second conductive wires;
first and second arms each having a proximal end and a distal end, the proximal ends of the first and second arms having first and second electrically conductive tips secured thereto, respectively, the distal ends of the first and second arms being secured to the proximal end of the housing;
a light source secured to the housing; and
light source indicator driver circuitry in the housing, the driver circuitry being configured to cause the light source to be placed in a first mode if a first control signal is received in the driver circuitry.

2. The probe device of claim 1, wherein the driver circuitry is further configured to cause the light source to be placed in a second mode if a second control signal is received in the driver circuitry.

3. The probe device of claim 2, further comprising:
a power supply in the housing, the power supply providing a source of electrical power for the light source.

4. The probe device of claim 2, wherein the first mode corresponds to activation of the light source, and wherein activation of the light source provides a visual indication that indicates that tips of the probe device are in electrical contact with contact areas on the DUT.

5. The probe device of claim 4, wherein the second mode corresponds to deactivation of the light source, and wherein deactivation of the light source provides a visual indication that indicates that the tips of the probe device are not in electrical contact with contact areas on the DUT.

6. The probe device of claim 2, wherein the first mode corresponds to activation of the light source, and wherein activation of the light source provides a visual indication that indicates that tips of the probe device are not in electrical contact with contact areas on the DUT.

7. The probe device of claim 6, wherein the second mode corresponds to deactivation of the light source, and wherein deactivation of the light source provides a visual indication that indicates that the tips of the probe device are in electrical contact with contact areas on the DUT.

8. The probe device of claim 7, wherein activation of the light source provides illumination of at least the first and second tips of the probe device and of first and second areas, respectively, on the DUT to facilitate a user in visually aligning the first and second tips with the first and second contact areas, respectively, on the DUT.

9. The probe device of claim 1, wherein placement of the light source in the first mode causes the light source to be illuminated, wherein illumination of the light source results in illumination of at least the first and second tips of the probe device and of first and second areas, respectively, on the DUT to facilitate a user in visually aligning the first and second tips with the first and second contact areas, respectively, on the DUT.

10. The probe device of claim 2, wherein the first mode corresponds to the light source outputting light of at least a first color, and wherein the second mode corresponds to the light source outputting light of at least a second color.

11. The probe device of claim 2, wherein the first and second control signals are sent over a wired connection from a scope apparatus to the probe device, the first and second control signals being received in receiver circuitry of the light source indicator driver circuitry.

12. The probe device of claim 2, wherein the first and second control signals are sent over a wireless communication link from a scope apparatus to the probe device, the probe device further comprising:
wireless receiver circuitry, the first and second control signals being received in the wireless receiver circuitry, the wireless receiver circuitry decoding the first and second control signals and providing the first and second decoded control signals to the light source indicator driver circuitry.

13. A system for measuring electrical signals on a device under test (DUT), the system comprising:
a probe device comprising:
a probe device housing having a proximal end and a distal end, the distal end of the housing being connected to first and second conductive wires;
first and second arms each having a proximal end and a distal end, the proximal ends of the first and second arms having first and second electrically conductive tips secured thereto, respectively, the distal ends of the first and second arms being secured to the proximal end of the housing;
a light source secured to the housing; and
light source indicator driver circuitry in the housing, the driver circuitry being configured to cause the light source to be placed in a first mode if a first control signal is received in the driver circuitry; and
a scope apparatus comprising processing circuitry, the processing circuitry being configured to receive electrical signals sensed by the first and second tips and sent over the first and second conductive wires, respectively, to the scope apparatus, the scope apparatus determining whether or not the electrical signals sensed by the first and second tips indicate that the first and second tips are in good electrical contact with first and second contact areas, respectively, on the DUT, wherein if the scope apparatus determines that the electrical signals sensed by the first and second tips indicate that the first and second tips are in good electrical contact with the first and second contact areas, respectively, on the DUT, the scope apparatus causes the first control signal to be sent over a communication link to the light source indicator driver circuitry.

14. The system of claim 13, wherein if the scope apparatus determines that the electrical signals sensed by the first and second tips indicate that the first and second tips are not in good electrical contact with the first and second contact areas, respectively, on the DUT, the scope apparatus causes a second control signal to be sent over the communication link to the light source indicator driver circuitry, the driver circuitry being further configured to cause the light source to be placed in a second mode if the second control signal is received in the driver circuitry.

15. The system of claim 14, wherein the first mode corresponds to activation of the light source, and wherein activation of the light source provides a visual indication that indicates that tips of the probe device are in electrical contact with contact areas on the DUT.

16. The system of claim 15, wherein the second mode corresponds to deactivation of the light source, and wherein deactivation of the light source provides a visual indication that indicates that the tips of the probe device are not in electrical contact with contact areas on the DUT.

17. The system of claim 14, wherein the first mode corresponds to activation of the light source, and wherein activation of the light source provides a visual indication that indicates that tips of the probe device are not in electrical contact with contact areas on the DUT.

18. The system of claim 17, wherein the second mode corresponds to deactivation of the light source, and wherein deactivation of the light source provides a visual indication that indicates that the tips of the probe device are in electrical contact with contact areas on the DUT.

19. The system of claim 18, wherein activation of the light source provides illumination of at least the first and second tips of the probe device and of first and second areas, respectively, on the DUT to facilitate a user in visually aligning the first and second tips with the first and second contact areas, respectively, on the DUT.

20. The system of claim 13, wherein placement of the light source in the first mode causes the light source to be illuminated, wherein illumination of the light source results in illumination of at least the first and second tips of the probe device and of first and second areas, respectively, on the DUT to facilitate a user in visually aligning the first and second tips with the first and second contact areas, respectively, on the DUT.

21. A method for using a probe device to measure electrical signals on a device under test (DUT), the system comprising:
in a processor, receiving an electrical signal sensed by the probe device and determining at least one characteristic of the sensed signal;
in the processor, determining whether or not said at least one characteristic indicates that first and second conductive tips of the probe device are in good electrical contact with first and second contact areas, respectively, on the DUT;
if a determination is made that the first and second tips are in good electrical contact with the first and second contact areas, respectively, on the DUT, causing a light source on the probe device to be placed in a first mode; and
if a determination is made that the first and second tips are not in good electrical contact with first and second contact areas, respectively, on the DUT, causing a light source on the probe device to be placed in a second mode.

22. The method of claim 21, wherein the first mode corresponds to activation of the light source, and wherein activation of the light source provides a visual indication that indicates that tips of the probe device are in electrical contact with contact areas on the DUT.

23. The method of claim 22, wherein the second mode corresponds to deactivation of the light source, and wherein deactivation of the light source provides a visual indication that indicates that the tips of the probe device are not in electrical contact with contact areas on the DUT.

24. The probe device of claim 21, wherein the first mode corresponds to activation of the light source, and wherein activation of the light source provides a visual indication that indicates that tips of the probe device are not in electrical contact with contact areas on the DUT, and wherein the second mode corresponds to deactivation of the light source, and wherein deactivation of the light source provides a visual indication that indicates that the tips of the probe device are in electrical contact with contact areas on the DUT.

25. The method of claim 21, wherein placement of the light source in the first mode causes the light source to be illuminated, wherein illumination of the light source results in illumination of at least the first and second tips of the probe device and of first and second areas, respectively, on the DUT to facilitate a user in visually aligning the first and second tips with the first and second contact areas, respectively, on the DUT.
